(19) United States
(12) Patent Application Publication
(10) Pub. No.: US 2012/0161178 A1
(43) Pub. Date: Jun. 28, 2012

(54) LED PACKAGE AND CHIP CARRIER THEREOF

(75) Inventors: HOU-TE LIN, Hsinchu (TW); JUNG-HSI FANG, Hsinchu (TW)

(73) Assignee: ADVANCED OPTOELECTRONIC TECHNOLOGY, INC., Hsinchu Hsien (TW)

(21) Appl. No.: 13/217,281

(22) Filed: Aug. 25, 2011

(30) Foreign Application Priority Data
Dec. 24, 2010 (CN) 201010602917.0

(51) Int. Cl. H01L 33/60; H05K 1/02

(52) U.S. Cl. 257/98; 174/262; 257/E33.056; 257/E33.072

(57) ABSTRACT

An LED package includes a chip carrier, an LED chip, and an encapsulation. The chip carrier includes a first surface, a second surface opposite to the first surface, and a side surface interconnecting the first surface and the second surface. The chip carrier includes an insulator defining two holes, and two electrodes. Each electrode includes a first contact end exposed on the first surface and separated from the side surface by the insulator, a second contact end exposed on the second surface, and a connecting portion connecting the first contact end to the second contact end; the connecting portion has a bent part received in the hole. The LED chip is mounted on the first surface of the chip carrier. The encapsulation covers the LED chip.

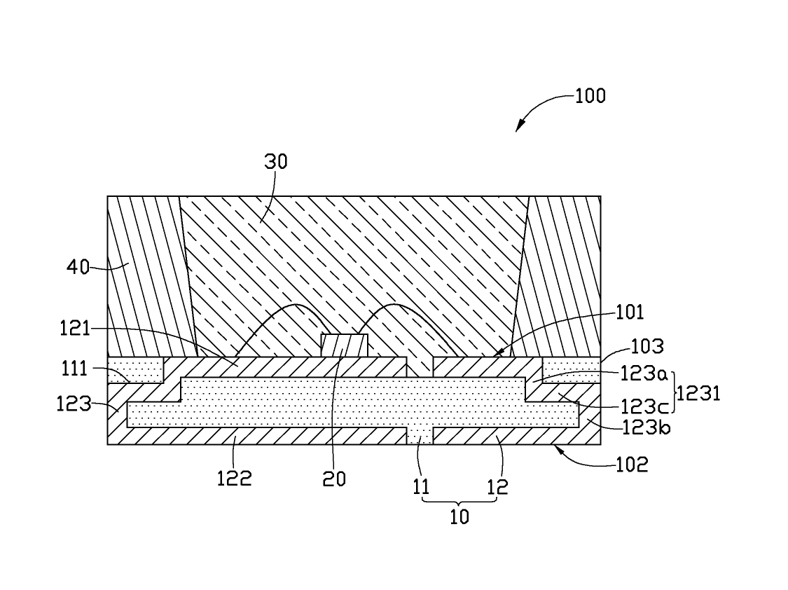

### BACKGROUND

1. Technical Field

The present disclosure relates to semiconductor packages and, particularly, to an LED (light emitting diode) package and a chip carrier of the LED package.

2. Description of Related Art

Light emitting diodes (LEDs) have many beneficial characteristics, including low electrical power consumption, low heat generation, long lifetime, small volume, good impact resistance, fast response and excellent stability. These characteristics have made the LEDs widely used in illuminating lamps or light sources of liquid crystal displays or other applications. Typically, a chip carrier of an LED package includes an insulator and two electrodes inserted into the insulator; the insulator is usually made of plastic material, and the electrodes are usually made of metal; it is difficult for the electrodes to completely tightly engage with the plastic material; as a result, water can enter the LED package easily through a gap between the insulator and the electrodes, thereby decreasing the lifetime of the LED package.

What is needed is an LED package and a chip carrier of the LED package which can ameliorate the problem of the prior art.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

The only drawing is a schematic, cross-sectional view of an LED package according to an exemplary embodiment of the present disclosure.

### DETAILED DESCRIPTION

Embodiments of the present disclosure will now be described in detail below, with reference to the accompanying drawing.

Referring to the only drawing, an LED package 100 according to an exemplary embodiment is shown. The LED package 100 includes a chip carrier 10, an LED chip 20, an encapsulation 30, and a reflective cup 40.

The chip carrier 10 includes an insulator 11 and two electrodes 12. The chip carrier 10 includes a first surface 101, a second surface 102 opposite to the first surface 101, and a side surface 103 connecting the first surface 101 and the second surface 102. The insulator 11 can be made of epoxy, silicone, silicon oxide or a mixture thereof. Preferably, the insulator 11 is made of thermally conductive and electrically insulating material. The electrodes 12 can be made of metal such as copper (Cu), nickel (Ni), silver (Ag), aluminum (Al), tin (Sn), gold (Au) or an alloy thereof, or made of oxides such as indium tin oxide (ITO).

Each of the two electrodes 12 includes a first contact end 121, a second contact end 122, and a connecting portion 123. The first contact end 121 is exposed on the first surface 101 of the chip carrier 10 and is separated from the side surface 103 by the insulator 11. The second contact end 122 is exposed on the second surface 102 of the chip carrier 10. The connecting portion 123 connects the first contact end 121 to the second contact end 122. The insulator 11 defines two holes 111 corresponding to the connecting portions 123 of the two electrodes 12 respectively. Each hole 111 extends from the first surface 101 to the side surface 103 of the insulator 11. Each connecting portion 123 has a bent part 1231 received in the hole 111; an inner surface of the hole 111 is fitted around the bent part 1231. In the present embodiment, a part of the connecting portion 123 is received in the hole 111. It is understood, in other embodiments, the connecting portion 123 can be totally received in the hole 111.

In the present embodiment, the connecting portion 123 includes a first extending section 123a connecting with the first contact end 121, a second extending section 123b connecting with the second contact end 122, and a third extending section 123c connecting the first extending section 123a to the second extending section 123b. The first extending section 123a and the third extending section 123c cooperatively form the bent part 1231, and are received in the hole 111. The first extending section 123a and the second extending section 123b are substantially perpendicular to the first surface 101 of the chip carrier 10, and the third extending section 123c is substantially parallel to the first surface 101 of the chip carrier 10.

The LED chip 20 is mounted on the first surface 101 of the chip carrier 10, and is electrically connected to the two electrodes 12. In the present embodiment, the LED chip 20 is mounted on the first contact end 121 of one electrode 12. The LED chip 20 can be electrically connected to the electrodes 12 by flip-chip, eutectic, or wires etc. In the present embodiment, the LED chip 20 is electrically connected to the electrodes 12 via two wires (not labeled).

The encapsulation 30 covers the LED chip 20 for protecting the LED chip 20 from dust, water or other foreign articles. The encapsulation 30 can be made of silicone, epoxy, or a mixture thereof. Preferably, the encapsulation 30 further includes fluorescent powder, such as YAG, TAG, silicate, nitride, nitrogen oxides, phosphide or sulfide. The fluorescent powder is used for changing color of light from the LED chip 20 into a different color.

The reflective cup 40 is disposed on the first surface 101 of the chip carrier 10 and surrounds the LED chip 20 and the encapsulation 30. The reflective cup 40 is configured for reflecting the light irradiating thereon to improve the amount of the light emitted out of the LED package 100. The reflective cup 40 can be made of a light reflective material completely, or only has an inner surface thereof is coated with a light reflective material. Preferably, the reflective cup 40 is made of thermally conductive and electrically insulating material. The reflective cup 40 can be integrally formed with the chip carrier 10.

In the LED package 100, because the part of the connecting portion 123 received in the hole 111 is bent, the contacting area between the connecting portion 123 and the electrode 12 is increased; thus, there will be a relatively large engagement strength between the connecting portion 123 and the electrode 12, and accordingly, there will be a smaller gap or no gap between the connecting portion 123 of the electrode 12 and the insulator 11; thus, water is difficult to enter the LED package 100 from a gap between the insulator 11 and the electrodes 12.

While certain embodiments have been described and exemplified above, various other embodiments will be apparent to those skilled in the art from the foregoing disclosure. The disclosure is not limited to the particular embodiments described and exemplified, and the embodiments are capable of considerable variation and modification without departure from the scope and spirit of the appended claims.

What is claimed is:

1. An LED package comprising:
a chip carrier comprising a first surface, a second surface opposite to the first surface, and a side surface interconnecting the first surface and the second surface, the chip carrier comprising:
an insulator defining two holes; and
two electrodes each comprising a first contact end exposed on the first surface and separated from the side surface by the insulator, a second contact end exposed on the second surface, and a connecting portion connecting the first contact end to the second contact end, the connecting portion having a bent part received in the hole;
an LED chip mounted on the first surface of the chip carrier and electrically connected to the first contact ends of the two electrodes; and
an encapsulation covering the LED chip.

2. The LED package as claimed in claim 1, wherein an inner surface the hole is fitted around the bent part.

3. The LED package as claimed in claim 1, wherein the connecting portion comprises a first extending section connecting with the first contact end, a second extending section connecting with the second contact end, and a third extending section connecting the first extending section to the second extending section, the first extending section and the third extending section cooperatively form the bent part, and are received in the hole.

4. The LED package as claimed in claim 3, wherein the first extending section is substantially perpendicular to the first surface of the chip carrier, and the third extending section is substantially parallel to the first surface of the chip carrier.

5. The LED package as claimed in claim 4, wherein the second extending section is substantially perpendicular to the first surface of the chip carrier.

6. The LED package as claimed in claim 1, wherein the insulator is made of epoxy, silicone, silicon oxide or a mixture thereof.

7. The LED package as claimed in claim 1, wherein the insulator is made of thermally conductive and electrically insulating material.

8. The LED package as claimed in claim 1, wherein the electrodes are made of metal or oxide.

9. The LED package as claimed in claim 8, wherein the electrodes are made of indium tin oxide (ITO), copper (Cu), nickel (Ni), silver (Ag), aluminum (Al), tin (Sn), gold (Au) or an alloy thereof.

10. The LED package as claimed in claim 1, wherein the encapsulation is made of silicone, epoxy, or a mixture thereof.

11. The LED package as claimed in claim 1, wherein the encapsulation comprises fluorescent powder.

12. The LED package as claimed in claim 1 further comprising a reflective cup, wherein the reflective cup is disposed on the first surface of the chip carrier and surrounds the LED chip and the encapsulation.

13. A chip carrier of an LED package comprising:
an insulator comprising a first surface, a second surface opposite to the first surface, and a side surface interconnecting the first surface and the second surface, and two holes each extending from the first surface to the side surface; and
two electrodes each comprising a first contact end exposed on the first surface and separated from the side surface by the insulator, a second contact end exposed on the second surface, and a connecting portion connecting the first contact end to the second contact end, the connecting portion having a bent part received in the hole.

14. The chip carrier as claimed in claim 13, wherein an inner surface the hole is fitted around the bent part.

15. The chip carrier as claimed in claim 13, wherein the connecting portion comprises a first extending section connecting with the first contact end, a second extending section connecting with the second contact end, and a third extending section connecting the first extending section to the second extending section, the first extending section and the third extending section cooperatively form the bent part, and are received in the hole.

16. The chip carrier as claimed in claim 15, wherein the first extending section is substantially perpendicular to the first surface of the chip carrier, and the third extending section is substantially parallel to the first surface of the chip carrier.

17. The chip carrier as claimed in claim 16, wherein the second extending section is substantially perpendicular to the first surface of the chip carrier.

18. The chip carrier as claimed in claim 13, wherein the insulator is made of epoxy, silicone, silicon oxide or a mixture thereof.

19. The chip carrier as claimed in claim 13, wherein the insulator is made of thermally conductive and electrically insulating material.

20. The chip carrier as claimed in claim 13, wherein the electrodes are made of metal or oxide.
